(19) United States
(12) Patent Application Publication
(10) Pub. No.: US 2014/0116505 A1
(43) Pub. Date: May 1, 2014

(54) RESIN COMPOSITION

(71) Applicant: Kazuya Ebara, Funabashi-shi (JP)

(72) Inventor: Kazuya Ebara, Funabashi-shi (JP)

(73) Assignee: NISSAN CHEMICAL INDUSTRIES, LTD., Tokyo (JP)

(21) Appl. No.: 14/118,121

(22) PCT Filed: May 25, 2012
(86) PCT No.: PCT/JP2012/063535

§ 371 Date: Dec. 11, 2013

(30) Foreign Application Priority Data
May 27, 2011 (JP) 2011-118949

(51) Int. Cl. C09D 133/08; H01L 31/048

(52) U.S. Cl. CPC C09D 133/08; H01L 31/0481
USPC 136/256; 524/720

(57) ABSTRACT

There is provided a resin composition capable of forming a cured film having excellent light resistance, high transparency, and a high refractive index. A resin composition including: a component (A); a component (B); and a component (C) below, in which the composition is formed into a film and is then heated at 150° C. or higher to achieve a refractive index of 1.65 or higher: the component (A): a triazine compound having at least two nitrogen atoms substituted with a hydroxymethyl group and/or an alkoxymethyl group; the component (B): an ethylene glycol compound having at least one acrylic moiety and having an aromatic group substituted with an organic group or a condensed aromatic group; and the component (C): an acid compound having a pKa of 2 or lower.

### TECHNICAL FIELD

The present invention relates to a resin composition and specifically relates to a resin composition capable of forming a cured film having excellent light resistance, high transparency, and a high refractive index.

### BACKGROUND ART

In recent years, plastic materials having a high refractive index have been extensively employed in optical articles and have been studied for the applications to, for example, eyeglass lenses, Fresnel lenses, lenticular lenses, aspheric lenses, optical discs, optical fibers, and optical waveguides. Furthermore, the field of electronic materials has been heavily employing transparent resins as optical electronic materials such as an anti-reflective coating agent for a liquid crystal display, a transparent coating agent for a solar battery, a light emitting diode, and a light receiver in a CCD or CMOS sensor. The application for such an optical electronic material often requires not only the transparency but also a high refractive index in order to improve light extraction efficiency and light-harvesting properties. The currently used transparent resin having a high refractive index is an acrylic resin, a urethane resin, or an epoxy resin.

Although mechanical properties of the related art transparent resin can be controlled to some extent by cross-linking or other techniques, improving optical characteristics, specifically, increasing the refractive index requires special techniques.

For example, Patent Documents 1 and 2 disclose techniques of bonding a large amount of heavy atoms such as bromine and sulfur to an organic resin to improve the refractive index of the organic resin.

Moreover, Patent Documents 3 and 4 disclose techniques of dispersing inorganic oxide fine particles having a high refractive index in an organic resin to improve the refractive index of the organic resin.

### PRIOR ART DOCUMENTS

### Patent Documents

Patent Document 1: Japanese Patent Application Publication No. H05-164901 (JP H05-164901 A)

Patent Document 2: Japanese Patent Application Publication No. 2005-350531 (JP 2005-350531 A)

Patent Document 3: Japanese Patent Application Publication No. 2007-270099 (JP 2007-270099 A)

Patent Document 4: Japanese Patent Application Publication No. 2007-308631 (JP 2007-308631 A)

### SUMMARY OF THE INVENTION

### Problem to be Solved by the Invention

The techniques in Patent Documents 1 and 2 produce an organic resin that is typically unstable with respect to heat or light and thus is likely to cause deterioration such as discoloration during long use. Moreover, the resin applied to an electronic material member may also cause, for example, electrode corrosion.

The techniques in Patent Documents 3 and 4 also have an issue in, for example, long-term storage stability of an obtained fine particle dispersion resin. Moreover, the techniques require a large amount of a dispersion stabilizer in order to improve the dispersion stability of the inorganic oxide fine particles in the resin, and this makes it difficult to balance the refractive index and the dispersion stability.

In view of the above circumstances, the present invention has an object to provide a resin composition capable of forming a cured film having excellent light resistance, high transparency, and a high refractive index without using a heavy atom or inorganic oxide fine particles.

### Means for Solving the Problem

As a result of repeated intensive studies in order to achieve the object, the inventors of the present invention have found that adding an ethylene glycol compound having at least one acrylic moiety and having an aromatic group substituted with an organic group or a condensed aromatic group to a resin composition allows the production of a cured film having excellent light resistance, high transparency, and a high refractive index, and have accomplished the present invention.

Specifically, the present invention relates to, as a first aspect, a resin composition comprising: a component (A); a component (B); and a component (C), in which the composition is formed into a film and is then heated at 150° C. or higher to achieve a refractive index of 1.65 or higher:
the component (A): a triazine compound having at least two nitrogen atoms substituted with a hydroxymethyl group and/or an alkoxymethyl group;
the component (B): an ethylene glycol compound having at least one acrylic moiety and having an aromatic group substituted with an organic group or a condensed aromatic group; and
the component (C): an acid compound having a pKa of 2 or lower.

According to a second aspect, the present invention relates to the resin composition according to the first aspect, in which the aromatic group substituted with an organic group in the component (B) is a carbomonocyclic aromatic group substituted with an organic group.

According to a third aspect, the present invention relates to the resin composition according to the second aspect, in which the carbomonocyclic aromatic group substituted with an organic group in the component (B) is a phenyl group substituted with a phenyl group.

According to a fourth aspect, the present invention relates to the resin composition according to the first aspect, in which the condensed aromatic group in the component (B) is a naphthyl group, an anthryl group, a phenanthryl group, or a pyrenyl group.

According to a fifth aspect, the present invention relates to the resin composition according to the third aspect, in which the ethylene glycol compound as the component (B) is a compound of Formula (1):

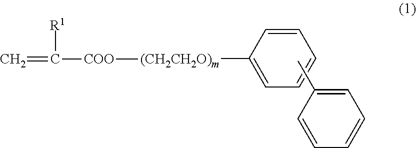

(where R¹ is a hydrogen atom or a methyl group, and m is a natural number).

According to a sixth aspect, the present invention relates to the resin composition according to the fifth aspect, in which m is 10 or less.

According to a seventh aspect, the present invention relates to the resin composition according to any one of the first aspect to the sixth aspect, in which the triazine compound as the component (A) is a compound having an aromatic group.

According to an eighth aspect, the present invention relates to the resin composition according to any one of the first aspect to the seventh aspect, in which the acid compound as the component (C) is a sulfonic acid compound.

According to a ninth aspect, the present invention relates to the resin composition according to the eighth aspect, in which the sulfonic acid compound is a compound of Formula (2) or Formula (3):

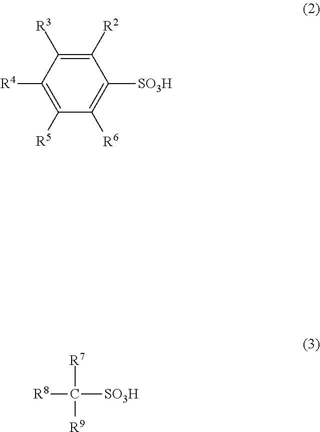

(where each of R² to R⁹ is independently a hydrogen atom, a C₁₋₁₀ alkyl group, a C₁₋₁₀ haloalkyl group, a C₁₋₁₀ alkoxy group, a halogen atom, a nitro group, a formyl group, a cyano group, a carboxy group, a phosphonyl group, a sulfonyl group, a phenyl group optionally substituted with W, a naphthyl group optionally substituted with W, a thienyl group optionally substituted with W, or a furyl group optionally substituted with W; and W is a C₁₋₁₀ alkyl group, a C₁₋₁₀ haloalkyl group, a C₁₋₁₀ alkoxy group, a hydroxy group, a halogen atom, a nitro group, a formyl group, a cyano group, or a carboxy group).

According to a tenth aspect, the present invention relates to the resin composition according to the ninth aspect, in which the compound of Formula (2) is tosic acid.

According to an eleventh aspect, the present invention relates to the resin composition according to any one of the first aspect to the tenth aspect further comprising at least one solvent selected from the group consisting of an alcohol having four or more carbon atoms or an alkyl ester having four or more carbon atoms as a component (D). According to a twelfth aspect, the present invention relates to the resin composition according to any one of the first aspect to the eleventh aspect, in which the component (B) is contained in a proportion of 300 parts by mass or less per 100 parts by mass of the component (A).

According to a thirteenth aspect, the present invention relates to the resin composition according to any one of the first aspect to the twelfth aspect, in which the component (C) is contained in a proportion of 10 parts by mass or less per 100 parts by mass of the component (A).

According to a fourteenth aspect, the present invention relates to the resin composition according to any one of the eleventh aspect to the thirteenth aspect, in which the component (D) is contained in a proportion of 0.1 parts by mass or more per the total mass part of the component (A), the component (B), and the component (C).

According to a fifteenth aspect, the present invention relates to the resin composition according to any one of the first aspect to the fourteenth aspect further comprising an adhesion agent having a silyl group as a component (E).

According to a sixteenth aspect, the present invention relates to a cured film obtained from the resin composition as described in any one of the first aspect to the fifteenth aspect.

According to a seventeenth aspect, the present invention relates to a solar battery obtained by applying the cured film as described in the sixteenth aspect onto a surface of a transparent electrode.

According to an eighteenth aspect, the present invention relates to an electronic part comprising the cured film as described in the sixteenth aspect.

### Effects of the Invention

A resin composition of the present invention can form a cured film having excellent light resistance, high transparency, and a high refractive index.

### BRIEF DESCRIPTION OF THE DRAWINGS

FIG. 1 is a view showing measurement results of transmittance before and after light resistance test in Example 1.

FIG. 2 is a view showing measurement results of refractive index before and after the light resistance test in Example 1.

### MODES FOR CARRYING OUT THE INVENTION

The present invention relates to a resin composition comprising: a component (A), a component (B), and a component (C), in which the composition is formed into a film and then is heated at 150° C. or higher to achieve a refractive index of 1.65 or higher.
The component (A): a triazine compound having at least two nitrogen atoms substituted with a hydroxymethyl group and/or an alkoxymethyl group
The component (B): an ethylene glycol compound having at least one acrylic moiety and having an aromatic group substituted with an organic group or a condensed aromatic group
The component (C): an acid compound having a pKa of 2 or lower

<Component (A): Triazine Compound>

The component (A) of the present invention is a triazine compound having at least two nitrogen atoms substituted with a hydroxymethyl group and/or an alkoxymethyl group.

Examples of the triazine compound having at least two nitrogen atoms substituted with a hydroxymethyl group and/or an alkoxymethyl group include a melamine compound having nitrogen atoms substituted with one or both of a hydroxymethyl group or an alkoxymethyl group and a benzoguanamine compound having nitrogen atoms substituted with one or both of a hydroxymethyl hydroxymethyl group and an alkoxymethyl group.

The melamine compound and the benzoguanamine compound having the nitrogen atoms substituted with a hydroxymethyl group can be obtained by, for example, hydroxymethylation of melamine/benzoguanamine with formalin in boiling water. The melamine compound and the benzoguanamine compound having the nitrogen atoms substituted with an alkoxymethyl group can be obtained by causing the melamine/benzoguanamine compound previously substituted with hydroxymethyl to react with an alcohol such as methanol, ethanol, isopropyl alcohol, and n-hexanol.

The melamine compound and the benzoguanamine compound substituted with a hydroxymethyl group and/or an alkoxymethyl group are commercially available. Examples of the melamine compound include Cymel 300, Cymel 303, Cymel 325, and Cymel 725 manufactured by Nihon Cytec Industries Inc., Nikalac MW-30M, Nikalac MW-30, Nikalac MW-30HM, Nikalac MW-390, and Nikalac MW-100LM manufactured by SANWA Chemical Co., Ltd. (methoxymethylated melamine compounds); Cymel 370 and Cymel 701 manufactured by Nihon Cytec Industries Inc. (methylated methoxymethylated melamine compounds); Cymel 266, Cymel 285, and Cymel 212 manufactured by Nihon Cytec Industries Inc. (methoxymethylated butoxymethylated melamine compounds); Cymel 272 and Cymel 202 manufactured by Nihon Cytec Industries Inc. (methylated methoxymethylated melamine compounds); Cymel 238 manufactured by Nihon Cytec Industries Inc. (a methoxymethylated isobutoxymethylated melamine compound); and Mycoat 506 manufactured by Nihon Cytec Industries Inc. (a butoxymethylated melamine compound). Examples of the benzoguanamine compound include Cymel 1123 manufactured by Nihon Cytec Industries Inc. (a methoxymethylated ethoxymethylated benzoguanamine compound); Cymel 1123-10 and Mycoat 30 manufactured by Nihon Cytec Industries Inc. (methoxymethylated butoxymethylated benzoguanamine compounds); Mycoat 105 and Mycoat 106 manufactured by Nihon Cytec Industries Inc. (methoxymethylated benzoguanamine compounds); Cymel 1128 manufactured by Nihon Cytec Industries Inc. (a butoxymethylated benzoguanamine compound); and Mycoat 102 manufactured by Nihon Cytec Industries Inc. (a methylated methoxymethylated benzoguanamine compound).

<Component (B): Ethylene Glycol Compound>

The component (B) of the present invention is an ethylene glycol compound having at least one acrylic moiety and having an aromatic group substituted with an organic group or a condensed aromatic group.

In the present invention, the aromatic group substituted with an organic group includes not only an aromatic group substituted with an organic group but also a heteroaromatic group substituted with an organic group. In the present invention, the condensed aromatic group includes not only a condensed aromatic group but also a condensed heteroaromatic group.

Examples of the aromatic group substituted with an organic group include, but are not limited to, a phenyl group substituted with a phenyl group, a pyrrolyl group substituted with a phenyl group, an indolyl group substituted with a phenyl group, a thienyl group substituted with a phenyl group, a phosphoryl group substituted with a phenyl group, a pyrazolyl group substituted with a phenyl group, an oxazolyl group substituted with a phenyl group, an imidazolyl group substituted with a phenyl group, a thiazolyl group substituted with a phenyl group, an isoxazolyl group substituted with a phenyl group, a pyridinyl group substituted with a phenyl group, a pyrazinyl group substituted with a phenyl group, a pyridazinyl group substituted with a phenyl group, and a triazinyl group substituted with a phenyl group.

Among them, the aromatic group substituted with an organic group is preferably a carbomonocyclic aromatic group substituted with an organic group, and is particularly preferably a phenyl group substituted with a phenyl group from the viewpoint of availability.

Examples of the condensed aromatic group include, but are not limited to, a naphthyl group, an anthryl group, a phenanthryl group, a pyrenyl group, a benzofuranyl group, an isobenzofuranyl group, an isoindolyl group, a benzothiophenyl group, a benzophosphoryl group, a benzoimidazolyl group, a puryl group, an indazolyl group, a benzoxazolyl group, a benzisoxazolyl group, a benzothiazolyl group, and a benzoimidazolyl group.

Among them, the condensed aromatic group is preferably a naphthyl group, an anthryl group, a phenanthryl group, or a pyrenyl group from the viewpoint of availability.

The ethylene glycol compound as the component (B) is preferably a compound of Formula (1) because the compound can yield a film having a higher refractive index.

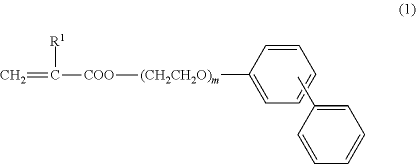

(In the formula, R¹ is a hydrogen atom or a methyl group, and m is a natural number)

In Formula (1), m is preferably 10 or less.

The resin composition of the present invention contains the ethylene glycol compound as the component (B) in an amount of 300 parts by mass or less, preferably 200 parts by mass or less from the viewpoint of film characteristics to be obtained, and more preferably 100 parts by mass or less from the viewpoint of storage stability and film formability, per 100 parts by mass of the component (A).

<Component (C): Acid Compound Having pKa of 2 or Lower>

The component (C) of the present invention is an acid compound having a pKa of 2 or lower.

In the present invention, the acid dissociation constant pKa is represented by the equation pKa=log₁₀Ka where Ka is the acid dissociation constant of an acidic compound dissolved in water.

The acid compounds may be used singly or in combination of two or more of them.

Examples of the acid compound include sulfonic acid compounds such as p-toluenesulfonic acid (also called tosic acid), trifluoromethanesulfonic acid, and pyridinium p-toluene sulfonate; and carboxylic acid compounds such as sulfosalicylic acid, trifluoroacetic acid, fumaric acid, and maleic acid. Among them, sulfonic acid compounds are preferred and the sulfonic acid compound of Formula (2) or Formula (3) is particularly preferred.

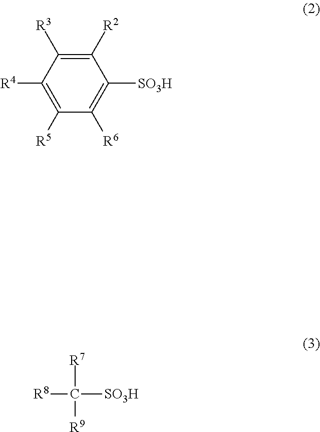

(In the formulae, each of R² to R⁹ is independently a hydrogen atom, a C₁₋₁₀ alkyl group, a C₁₋₁₀ haloalkyl group, a C₁₋₁₀ alkoxy group, a halogen atom, a nitro group, a formyl group, a cyano group, a carboxy group, a phosphonyl group, a sulfonyl group, a phenyl group optionally substituted with W, a naphthyl group optionally substituted with W, a thienyl group optionally substituted with W, or a furyl group optionally substituted with W; and
W is a C₁₋₁₀ alkyl group, a C₁₋₁₀ haloalkyl group, a C₁₋₁₀ alkoxy group, a hydroxy group, a halogen atom, a nitro group, a formyl group, a cyano group, or a carboxy group.)

The component (C) of the present invention is particularly preferably p-toluenesulfonic acid (also called tosic acid).

The resin composition of the present invention contains the acid compound as the component (C) in an amount of 10 parts by mass or less, preferably 5 parts by mass or less from the viewpoint of film characteristics to be obtained, and more preferably 3 parts by mass or less from the viewpoint of storage stability, per 100 parts by mass of the component (A).

<Component (D): Solvent>

The resin composition of the present invention may contain at least one solvent selected from the group consisting of an alcohol having four or more carbon atoms and an alkyl ester having four or more carbon atoms as a component (D).

The solvents may be used singly or in combination of two or more of them.

Examples of the solvent include butyl cellosolve, propylene glycol monomethyl ether, propylene glycol monomethyl ether acetate, dipropylene glycol monomethyl ether, γ-butyrolactone, n-butanol, sec-butanol, t-butanol, methoxymethylpentanol, methyl cellosolve, ethyl cellosolve, methyl cellosolve acetate, ethyl cellosolve acetate, butyl carbitol, butyl carbitol acetate, ethyl carbitol, ethyl carbitol acetate, ethylene glycol monoisopropyl ether, ethylene glycol monobutyl ether, dipropylene glycol monoacetate monomethyl ether, dipropylene glycol monoethyl ether, dipropylene glycol monoacetate monoethyl ether, dipropylene glycol monopropyl ether, dipropylene glycol monoacetate monopropyl ether, 2-ethoxyethanol, 2-butoxyethanol, methyl lactate, ethyl lactate, butyl lactate, methyl acetate, ethyl acetate, n-butyl acetate, hexyl acetate, methyl 2-hydroxyisobutyrate, propylene glycol monoethyl ether acetate, methyl pyruvate, ethyl pyruvate, methyl 3-methoxypropionate, methylethyl 3-ethoxypropionate, ethyl 3-methoxypropionate, propyl 3-methoxypropionate, butyl 3-methoxypropionate, and butyl butyrate.

The resin composition of the present invention contains the solvent as the component (D) in an amount of 0.1 parts by mass or more per the total mass part of the component (A), the component (B), and the component (C).

<Component (E): Adhesion Agent>

The resin composition of the present invention may further contain an adhesion agent having a silyl group as a component (E) in addition to the components above.

Examples of the adhesion agent include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, N-phenyl-3-aminopropyltrimethoxysilane, 3-ureidopropyltriethoxysilane, 3-chloropropyltrimethoxysilane, 3-mercaptopropylmethyldimethoxysilane, 3-mercaptopropyltrimethoxysilane, bis(triethoxysilylpropyl)tetrasulfide, 3-isocyanate propyltriethoxysilane, and 3-aminopropyldiethoxymethylsilane.

In the present invention, the adhesion agent, if used, is preferably added in an amount of less than 10 parts by mass, and is more preferably 5 parts by mass or less from the viewpoint of storage stability, per 100 parts by mass of the component (A).

<Additional Components>

The resin composition of the present invention may contain commonly used additional additives such as a surfactant.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonyiphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants including EFTOPs EF301, EF303, and EF352 (manufactured by Jemco (formerly Tochem Products)), MEGAFACs F171, F173, and R-30 (manufactured by DIC Corporation (formerly Dainippon Ink and Chemicals, Inc.)), Fluorads FC 430 and FC431 (manufactured by Sumitomo 3M), Asahiguard AG710, Surflons S-382, SC101, SC102, SC103, SC104, SC105, and SC106 (manufactured by Asahi Glass Co., Ltd.); and an organosiloxane polymer KP341 (manufactured by Shin-Etsu Chemical Co., Ltd.).

The surfactant is typically contained in an amount of 0.2% by mass or less and preferably 0.1% by mass or less in the total components of the resin composition of the present invention. These surfactants may be added singly or in combination of two or more of them.

<Solar Battery>

The resin composition of the present invention is applicable to the material for various silicon solar batteries that have been developed.

The solar battery typically includes a solar battery cell composed of a transparent electrode (front side electrode), a photoelectric conversion layer, and a backside electrode and a panel mounting the solar battery cell and including a sealer such as an ethylene vinyl acetate copolymer resin (EVA) for sealing a cell module, a surface glass (tempered glass) for protecting the cell module and the sealer, and a protective film (back sheet).

The present invention can employ various constituents, that is, a solar battery cell (a backside electrode, a photoelectric conversion layer, and a transparent electrode), a sealer, a surface glass, a protective film, and various electrode protection materials, that have been developed for constituting a solar battery.

In a practical manner, the resin composition of the present invention is applied onto the surface of a transparent electrode of a solar battery cell to form an electrode surface-coating film. Then, a tempered glass, a sealer, the solar battery cell (the electrode surface-coating film, the transparent electrode, a photoelectric conversion layer, and a backside electrode), a sealer, and a back sheet are stacked in this order to yield a solar battery.

### EXAMPLES

The present invention will be described in further detail with reference to Examples, but the present invention is not limited to Examples.

### Abbreviations in Examples

The abbreviations used in Examples below are as follows:

### <Monomers/Cross-Linking Materials>

Cymel 1123: a melamine compound (methoxymethylated benzoguanamine compound) manufactured by Nihon Cytec Industries Inc.
A-len-10: an acrylic compound (ethoxylated O-phenylphenol acrylate) manufactured by Shin Nakamura Chemical Co., Ltd.
A-TMM-3 LM-N: an acrylic compound (pentaerythritol triacrylate (triester 57%)) manufactured by Shin Nakamura Chemical Co., Ltd.

### <Organic Solvents>

PGMEA: propylene glycol monomethyl ether acetate
PGME: propylene glycol monomethyl ether
HBM: methyl 2-hydroxyisobutyrate
NMP: N-methylpyrrolidone
CHN: cyclohexanone
EL: ethyl lactate

HA: hexyl acetate

### <Acid Compound>

PTA: p-toluenesulfonic acid

### <Surfactants>

FTX-212P: manufactured by Neos Company Ltd.
FTX-220P: manufactured by Neos Company Ltd.

[Sample Coating]

A resin composition was applied onto a substrate with Spin Coater 1H-DX2 manufactured by MIKASA CO., LTD.

[Measurement of Transmittance]

UV-VIS Spectrophotometer UV-3100PC manufactured by Shimadzu Corporation was used for measurement. The transmittance at 400 nm is described.

[Measurement of Refractive Index]

High speed spectroscopic ellipsometer M-2000 manufactured by J.A. Woollam JAPAN Co., Inc. was used for measurement. The refractive index at 633 nm is described.

[Light Resistance Test]

Atlas, Weather-Ometer Ci4000 manufactured by Toyo Seiki Seisaku-sho, Ltd. was used. The measurement condition was at 60 w/m² (a wavelength from 300 to 400 nm) for 50 hours with a xenon arc lamp and at a temperature of 63±3 degrees with a black panel.

[Synthesis of Resin Composition: Varnish 1]

Into a 100-mL recovery flask containing 40.1 g of HBM dissolving 0.15 g of p-toluenesulfonic acid (tosic acid), 5.00 g of Cymel 1123, 5.00 g of A-len-10, and 0.0002 g of a surfactant were charged, and the whole was stirred at room temperature (around 25° C.) for 3 hours or more to afford a homogeneous solution, thus yielding a resin composition. The obtained solution was colorless and transparent.

[Synthesis of Resin Composition: Varnishes 2 to 11]

In accordance with the formulations shown in Table 1, a melamine compound as the component (A), an acrylic compound as the component (B), an acid compound as the component (C), an organic solvent as the component (D), and 0.0002 g of a surfactant were mixed and stirred at room temperature (around 25° C.) for 3 hours or more to afford a homogeneous solution as a resin composition. Each component and the surfactant type are described.

TABLE 1
Formulation of Resin Composition

| | Component (A) | Component (B) | Component (C) | Component (D) | |
|---|---|---|---|---|---|
| | (g) | (g) | (g) | (g) | Surfactant |
| Varnish 1 | Cymel 1123 | A-len-10 | PTA | HBM | FTX-212P |
| | 5.00 | 5.00 | 0.15 | 40.1 | |
| Varnish 2 | Cymel 1123 | A-len-10 | PTA | PGMEA | FTX-220P |
| | 5.00 | 5.00 | 0.15 | 40.1 | |
| Varnish 3 | Cymel 1123 | A-len-10 | PTA | PGME | FTX-212P |
| | 5.00 | 5.00 | 0.15 | 40.1 | |
| Varnish 4 | Cymel 1123 | A-len-10 | PTA | CHN | FTX-212P |
| | 5.00 | 5.00 | 0.15 | 40.1 | |
| Varnish 5 | Cymel 1123 | A-len-10 | PTA | EL | FTX-212P |
| | 5.00 | 5.00 | 0.15 | 40.1 | |
| Varnish 6 | Cymel 1123 | A-len-10 | PTA | PGMEA/HA | FTX-212P |
| | 5.00 | 5.00 | 0.15 | 32.0/8.1 | |
| Varnish 7 | Cymel 1123 | A-len-10 | PTA | PGMEA | FTX-212P |
| | 5.00 | 5.00 | 0.10 | 40.1 | |
| Varnish 8 | Cymel 1123 | A-len-10 | PTA | PGMEA | FTX-212P |
| | 5.00 | 1.25 | 0.15 | 24.7 | |
| Varnish 9 | Cymel 1123 | A-len-10 | PTA | PGMEA | FTX-212P |
| | 5.00 | 10.0 | 0.15 | 59.7 | |
| Varnish | Cymel 1123 | A-TMM-3 | PTA | PGMEA | FTX-212P |
| 10 | 5.00 | LM-N | 0.15 | 24.7 | |
| | | 0.25 | | | |
| Varnish | Cymel 1123 | A-TMM-3 | PTA | PGMEA | FTX-212P |
| 11 | 5.00 | LM-N | 0.15 | 59.7 | |
| | | 10.0 | | | |

### Production of Coating Film and Measurement of Refractive Index: Example 1

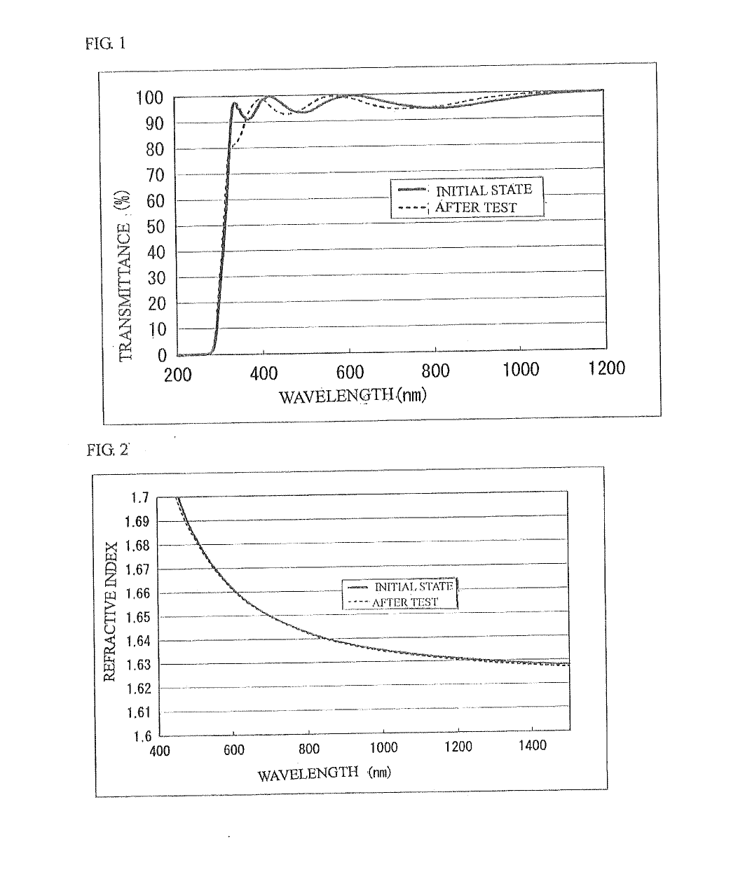

The varnish 1 prepared above was applied onto a silicon substrate and a quartz glass and cured at 180 degrees for 10 minutes, thus producing coating films having thicknesses of 0.3 μm and 1.0 μm, respectively. Then, the transmittance and the refractive index were measured before and after light resistance test and the changes in the transmittance and the refractive index before and after the test were observed (FIG. 1, FIG. 2). The results revealed that the transmittance was from 97.4% to 98.6% and the coating film maintained to have high transparency. The refractive index maintained 1.66. Thus, no great change was observable.

### Production of Coating Film and Measurement of Refractive Index: Examples 2 to 11, Comparative Examples 1 and 2

The varnishes prepared in accordance with Table 1 were applied onto a Si substrate with a spin coater and cured in a curing condition shown in Table 2 to form a film, and the refractive index was measured.

TABLE 2

| | | | Refractive | Refractive Index After |
|---|---|---|---|---|
| | Varnish | Curing Condition | Index | Light Resistance Test |
| Example 1 | varnish 1 | 150 degrees, 10 minutes | 1.66 | 1.66 |
| Example 2 | varnish 1 | 180 degrees, 10 minutes | 1.66 | 1.67 |
| Example 3 | varnish 1 | 230 degrees, 10 minutes | 1.67 | 1.67 |
| Example 4 | varnish 2 | 180 degrees, 10 minutes | 1.66 | 1.66 |
| Example 5 | varnish 3 | 180 degrees, 10 minutes | 1.66 | 1.66 |
| Example 6 | varnish 4 | 180 degrees, 10 minutes | 1.66 | 1.66 |
| Example 7 | varnish 5 | 180 degrees, 10 minutes | 1.66 | 1.66 |
| Example 8 | varnish 6 | 180 degrees, 10 minutes | 1.66 | 1.66 |
| Example 9 | varnish 7 | 180 degrees, 10 minutes | 1.66 | 1.66 |
| Example 10 | varnish 8 | 180 degrees, 10 minutes | 1.66 | 1.66 |
| Example 11 | varnish 9 | 180 degrees, 10 minutes | 1.66 | 1.66 |
| Comparative | varnish 10 | 180 degrees, 10 minutes | 1.64 | — |
| Example 1 | | | | |
| Comparative | varnish 11 | 180 degrees, 10 minutes | 1.59 | — |
| Example 2 | | | | |

The varnishes 10 and 11 prepared above were each applied onto a silicon substrate and a quartz glass and cured at 180 degrees for 10 minutes, thus producing coating films each having a thickness of 0.3 μm. Then, the refractive indexes were measured to be 1.64 and 1.59 (Comparative Examples 1 and 2). The result revealed that increasing an acrylic moiety lowered the refractive index.

1. A resin composition comprising:
a component (A);
a component (B); and
a component (C), wherein the composition is formed into a film and then is heated at 150° C. or higher to achieve a refractive index of 1.65 or higher:
the component (A): a triazine compound having at least two nitrogen atoms substituted with a hydroxymethyl group and/or an alkoxymethyl group;
the component (B): an ethylene glycol compound having at least one acrylic moiety and having an aromatic group substituted with an organic group or a condensed aromatic group; and
the component (C): an acid compound having a pKa of 2 or lower.

2. The resin composition according to claim 1, wherein the aromatic group substituted with an organic group in the component (B) is a carbomonocyclic aromatic group substituted with an organic group.

3. The resin composition according to claim 2, wherein the carbomonocyclic aromatic group substituted with an organic group in the component (B) is a phenyl group substituted with a phenyl group.

4. The resin composition according to claim 1, wherein the condensed aromatic group in the component (B) is a naphthyl group, an anthryl group, a phenanthryl group, or a pyrenyl group.

5. The resin composition according to claim 3, wherein the ethylene glycol compound as the component (B) is a compound of Formula (1): 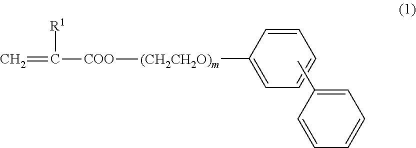
(where R¹ is a hydrogen atom or a methyl group, and m is a natural number).

6. The resin composition according to claim 5, wherein m is 10 or less.

7. The resin composition according to claim 1, wherein the triazine compound as the component (A) is a compound having an aromatic group.

8. The resin composition according to claim 1, wherein the acid compound as the component (C) is a sulfonic acid compound.

9. The resin composition according to claim 8, wherein the sulfonic acid compound is a compound of Formula (2) or Formula (3): 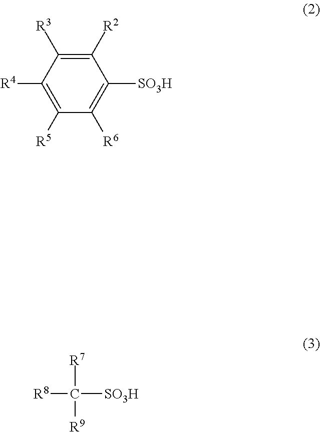
(where each of R² to R⁹ is independently a hydrogen atom, a C₁₋₁₀ alkyl group, a C₁₋₁₀ haloalkyl group, a C₁₋₁₀ alkoxy group, a halogen atom, a nitro group, a formyl group, a cyano group, a carboxy group, a phosphonyl group, a sulfonyl group, a phenyl group optionally substituted with W, a naphthyl group optionally substituted with W, a thienyl group optionally substituted with W, or a furyl group optionally substituted with W; and W is a C₁₋₁₀ alkyl group, a C₁₋₁₀ haloalkyl group, a C₁₋₁₀ alkoxy group, a hydroxy group, a halogen atom, a nitro group, a formyl group, a cyano group, or a carboxy group).

10. The resin composition according to claim 9, wherein the compound of Formula (2) is tosic acid.

11. The resin composition according to claim 1, further comprising at least one solvent selected from the group consisting of an alcohol having four or more carbon atoms or an alkyl ester having four or more carbon atoms as a component (D).

12. The resin composition according to claim 1, wherein the component (B) is contained in a proportion of 300 parts by mass or less per 100 parts by mass of the component (A).

13. The resin composition according to claim 1, wherein the component (C) is contained in a proportion of 10 parts by mass or less per 100 parts by mass of the component (A).

14. The resin composition according to claim 11, wherein the component (D) is contained in a proportion of 0.1 parts by mass or more per the total mass part of the component (A), the component (B), and the component (C).

15. The resin composition according to claim 1, further comprising an adhesion agent having a silyl group as a component (E).

16. A cured film obtained from the resin composition as claimed in claim 1.

17. A solar battery obtained by applying the cured film as claimed in claim 16 onto a surface of a transparent electrode.

18. An electronic part comprising the cured film as claimed in claim 16.
